(19) United States
(12) Patent Application Publication
(10) Pub. No.: US 2026/0305128 A1
(43) Pub. Date: Oct. 1, 2026

(54) DISPLAY MODULE, DISPLAY DEVICE, AND MANUFACTURING METHOD THEREFOR

(71) Applicant: Xiamen Tianma Display Technology Co., Ltd., Xiamen (CN)

(72) Inventors: Zhiwei WANG, Xiamen (CN); Jinjin Yang, Xiamen (CN)

(73) Assignee: Xiamen Tianma Display Technology Co., Ltd., Xiamen (CN)

(21) Appl. No.: 19/260,275

(22) Filed: Jul. 3, 2025

(30) Foreign Application Priority Data
Mar. 28, 2025 (CN) 202510380320.2

(51) Int. Cl. H10K 59/80; H10K 102/00

(52) U.S. Cl. CPC H10K 59/8722; H10K 59/872; H10K 59/873; H10K 2102/311

(57) ABSTRACT

The present application provides a display module, a display device, and a manufacturing method therefor. The display module comprises a display panel, a cover plate, a limiting member and an encapsulation adhesive. The cover plate is provided on one side of the display panel in a thickness direction thereof. The limiting member is connected to one side of the display panel away from the cover plate. A limiting portion is provided on one side of the limiting member away from the display panel, and the limiting portion is used for matching and assembling with a mid-frame. The encapsulation adhesive is provided on an outer peripheral side of the display panel. In a direction parallel to a plane on which the cover plate is located, the limiting member and the cover plate are provided exceeding the display panel to form a groove-like structure for accommodating the encapsulation adhesive.

### CROSS-REFERENCE TO RELATED APPLICATION

This application claims priority to Chinese Patent Application No. 202510380320.2, filed on Mar. 28, 2025, which is hereby incorporated by reference in its entirety.

### TECHNICAL FIELD

The present application relates to the technical field of display apparatus, and in particular to a display module, a display device, and a manufacturing method therefor.

### BACKGROUND

With the development of display technology, display devices (such as mobile phones, tablets, wearable bracelets, or televisions) have been widely used, and users' requirements for display devices have gradually escalated. The display devices are gradually becoming lighter and thinner, and full-screen. However, this also causes an increasing difficulty in manufacturing the display devices and higher requirements of the manufacturing process.

### SUMMARY

Embodiments of the present application provide a display module, a display device, and a manufacturing method therefor, which can release the space of the whole device.

In a first aspect, embodiments of the present application provide a display module. The display module comprises a display panel, a cover plate, a limiting member and an encapsulation adhesive. The cover plate is provided on a side of the display panel in a thickness direction thereof. The limiting member is connected to a side of the display panel away from the cover plate. A limiting portion is provided on a side of the limiting member away from the display panel, and the limiting portion is configured to fit with a mid-frame. The encapsulation adhesive is provided on an outer peripheral side of the display panel. The limiting member and the cover plate are provided exceeding the display panel to form a groove-like structure for accommodating the encapsulation adhesive in a direction parallel to a plane on which the cover plate is located.

In a second aspect, embodiments of the present application provide a display device, which comprises a mid-frame and a display module according to any one of the preceding embodiments. A surface of the mid-frame in the thickness direction is recessed inward to form an accommodation groove; a bottom surface of the accommodation groove is recessed inward to form a limiting groove; the display panel is located in the accommodation groove; and the limiting member is partially located in the limiting groove.

In a third aspect, embodiments of the present application provide a manufacturing method for a display device, comprising: attaching a display panel to a cover plate, the cover plate being provided on a side of the display panel in a thickness direction thereof; connecting the display panel with a limiting member, wherein the limiting member is located on a side of the display panel away from the cover plate, and the limiting member and the cover plate are provided exceeding the display panel to form a groove-like structure; forming an encapsulation adhesive within the groove-like structure; and fixing the display panel and a mid-frame in a fitting manner, where a surface of the mid-frame in the thickness direction is recessed inward to form an accommodation groove, a bottom surface of the accommodation groove is recessed inward to form a limiting groove, the display panel is located in the accommodation groove, and the limiting portion is located in the limiting groove.

The embodiments of the present application provide a display module, a display device and a method manufacturing therefor same. The display module may have the groove-like structure for accommodating the encapsulation adhesive by adding the limiting member in the display module, and defining a dimension and a shape of the limiting member and its position relative to the display panel, whereby a molding reliability of the encapsulation adhesive can be improved, and the occurrence possibility of problems such as adhesive overflow and adhesive shortage can be reduced. Moreover, in the finally formed display device, the limiting member may also be assembled and fitted with the mid-frame, such that a relative position between the display module and the mid-frame can be defined by the limiting member, a risk of excessive displacement of the display module relative to the mid-frame can be reduced, and an impact resistance and operational reliability of the display device can be improved.

### BRIEF DESCRIPTION OF THE DRAWINGS

FIG. 1 shows a structural schematic view of a display module according to an embodiment of the present application;

FIG. 2 shows a cross-sectional structural schematic view of FIG. 1 taken along A-A;

FIG. 3 shows a schematic structural view of a display module according to another embodiment of the present application;

FIG. 4 shows a cross-sectional structural schematic view of FIG. 3 taken along B-B;

FIG. 5 shows a cross-sectional structural schematic view of a display device according to an embodiment of the present application;

FIGS. 6A to 6D show cross-sectional structural schematic views of a display module according to another embodiment of the present application;

FIG. 7 shows a cross-sectional structural schematic view of a display module according to yet another embodiment of the present application;

FIG. 8 shows a cross-sectional structural schematic view of FIG. 1 taken along C-C in FIG. 1;

FIG. 9 shows a cross-sectional structural schematic view of a display module according to still yet another embodiment of the present application;

FIG. 10 shows a schematic structural view of a display module according to yet another embodiment of the present application;

FIG. 11 shows a cross-sectional view of a display module according to even still yet another embodiment of the present application;

FIG. 12 shows a cross-sectional view of a display device according to another embodiment of the present application;

FIG. 13 shows a cross-sectional view of another display module according to even still yet another embodiment of the present application;

FIG. 14 shows a cross-sectional view of another display module according to even still yet another embodiment of the present application;

FIG. 15 shows a cross-sectional view of another display module according to even still yet another embodiment of the present application;

FIG. 16 shows a cross-sectional view of another display device according to yet another embodiment of the present application;

FIG. 17 shows a cross-sectional view of another display device according to still yet another embodiment of the present application;

FIG. 18 shows a flow chart of a manufacturing method of a display device according to an embodiment of the present application; and

FIGS. 19A to 19D show schematic structural views of steps of a manufacturing method of a display device according to an embodiment of the present application.

### REFERENCE SIGNS

100 display module; 200 display device;
10 display panel; 11 display portion; 12 bending portion; 13 binding portion; 131 body portion; 132 driver chip; 133 protection portion; 14 support layer;
20 cover plate; 21 cover plate body; 22 curved portion;
30 limiting member; 31 limiting portion; 32 avoidance hole; 33 connection portion; 34 via-hole structure; 30a a first limiting sub-portion; 30b a second limiting sub-portion;
40 encapsulation adhesive;
50 mid-frame; 51 accommodation groove; 52 limiting groove; 53 bottom plate; 54 side plate;
60 blocking member; 61 a first portion; 62 buffer portion;
70 adhesive layer;
80 adhesive structure; 81 a first adhesive portion; 82 a second adhesive portion; 83 a third adhesive portion;
X a first direction; Y a second direction; Z thickness direction.

### DETAILED DESCRIPTION

Features and exemplary embodiments of various aspects of the present application will be described in detail below. In order to make the objects, technical solutions and advantages of the present application more clear, the present application will be further described in detail below with reference to the drawings and specific embodiments. It should be understood that, the specific embodiments described herein are only intended to explain the present application, but not to limit the present application. For those of ordinary skilled in the art, the present application may be implemented without some of those specific details. The following description of the embodiments is only for providing a better understanding of the present application by showing examples.

It should be noted that, relational terms such as first, second, and the like are used herein merely for distinguishing one entity or operation from another without necessarily requiring or implying any such actual relationship or order between such entities or operations. Moreover, the terms “include”, “comprise”, or any other variation thereof, are intended to cover a non-exclusive inclusion, such that a(n) process, method, article or device that includes a series of elements not only includes those elements but also includes other elements not explicitly listed or also includes elements inherent to such process, method, article or device. An element preceded by “include . . . ” does not, without more constraints, preclude the existence of additional identical elements in the process, method, article or device that includes the element.

With the development of science and technology, display devices are gradually developing, and full-screen display devices have emerged as the times demand. Under the demand for full-screen, it is necessary to reduce the bezel dimensions of the display device. After the bezel dimensions are reduced, the overall protective performance of the display device will also decrease. However, to meet the actual operational requirements, the display device needs to have sufficiently high performances such as sweat stain resistance and oil resistance.

On this basis, in the related art, adhesive is applied on the peripheral sides of the display module to prevent sweat, alkali, and oil from entering the module to improve the operational reliability of the finally formed display device. However, limited by factors such as process accuracy, it shows that the adhesive on the peripheral sides of the display module has problems such as poor coating accuracy, large fluctuations, and adhesive overflow and adhesive shortage.

In view of the above problems, in a first aspect, referring to FIGS. 1 to 5, the embodiments of the present application provide a display module 100. The display module 100 includes a display panel 10, a cover plate 20, a limiting member 30, and an encapsulation adhesive 40. The cover plate 20 is provided on a side of the display panel 10 in a thickness direction Z thereof. The limiting member 30 is connected to a side of the display panel 10 away from the cover plate 20. A limiting portion 31 is provided on a side of the limiting member 30 away from the display panel 10 and configured to fit with a mid-frame 50. The encapsulation adhesive 40 is provided on an outer peripheral side of the display panel 10. In a direction parallel to a plane on which the cover plate 20 is located, the limiting member 30 and the cover plate 20 extend beyond the display panel 10 to form a groove-like structure C for accommodating the encapsulation adhesive 40.

The display module 100 is a main component for forming a display device 200. In addition to the display module 100, the display device 200 further includes the mid-frame 50, which is a hollow structural frame. At least a part of the structure of the display module 100 is accommodated in the mid-frame 50, which can fix and protect the display module 100. Optionally, the mid-frame 50 includes at least one of a plastic material and a metal material.

The display panel 10 is a functional component for achieving a display effect in the display module 100 including a light-emitting structure which may have various forms. For example, the light-emitting structure may include an organic light-emitting component, such that the finally formed display device 200 is an organic light-emitting display device 200, or the light-emitting structure may include a micro light-emitting diode, such that the finally formed display device 200 is a micro light-emitting display device 200.

The cover plate 20 is a functional component for protecting the display panel 10 in the display module 100. The cover plate 20 is provided on a side of the display panel 10 in the thickness direction Z thereof. For example, the cover plate 20 may be located on a light-emitting surface side of the display panel 10, and may be bonded and fixed to the display panel 10. The material composition of the cover plate 20 is not limited in the embodiments of the present application. Optionally, the cover plate 20 may include a rigid material. In this case, a surface of the cover plate 20 may be flat such that the finally formed display device 200 has a straight screen structure. Alternatively, the cover plate 20 may include a flexible material. In this case, at least a partial area of a surface of the cover plate 20 may be curved such that the finally formed display device 200 has a curved screen structure.

In the direction parallel to the plane on which the cover plate 20 is located, a partial structure of the cover plate 20 extends beyond the display panel 10. Optionally, an outer contour of a projection of the display panel 10 in the thickness direction Z may be retracted relative to an outer contour of a projection of the cover plate 20 in the thickness direction Z. Furthermore, an ink layer may be provided at a position where the cover plate 20 is provided exceeding the display panel 10, and the ink layer has a certain light shielding effect, which helps to reduce the reflection problem of the finally formed display device 200 and improve the display effect.

It should be noted that the display panel 10 typically includes multiple film layers arranged in a stacked manner, and a thickness direction Z of the multiple film layers in the display panel 10 is typically parallel to the thickness direction Z of the display panel 10. In addition, a thickness direction Z of the cover plate 20 and a thickness direction Z of the entire display module 100 are also typically parallel to the thickness direction Z of the display panel 10. On this basis, in order to facilitate expression and understanding, in the drawings, these thickness directions Z are illustrated in a same direction in the embodiments of the present application.

Furthermore, the expression “projection in the thickness direction Z” mentioned in the embodiments of the present application refers to an orthographic projection on any plane perpendicular to the thickness direction Z. Since the plane on which the cover plate 20 is located is perpendicular to the thickness direction Z, a projection in the thickness direction Z may be an orthographic projection on the plane on which the cover plate 20 is located. The expression “projection in the thickness direction Z” mentioned in the subsequent embodiments of the present application has the same meaning, which will not be repeated in the present application.

The limiting member 30 is provided on a side of the display panel 10 away from the cover plate 20, that is, the limiting member 30 and the cover plate 20 are provided on different sides of the display panel 10 in the thickness direction Z, respectively. Specifically, the cover plate 20 is provided on the light-emitting surface side of the display panel 10, while the limiting member 30 is provided on a backlight surface side of the display panel 10. The limiting member 30 is connected to the display panel 10, and the connection therebetween includes, but is not limited to, bonding connection, screw connection, and welding connection.

Similar to the cover plate 20, in the direction parallel to the plane on which the cover plate 20 is located, the limiting member 30 and the cover plate 20 extend beyond the display panel 10 to form a groove-like structure C for accommodating the encapsulation adhesive 40. The groove-like structure C is configured to accommodate at least a partial structure of the encapsulation adhesive 40. In the related art, the groove-like structure C does not exist in the display module 100, and the encapsulation adhesive 40 drips on the peripheral sides of the display module 100 by dispensing. Under this condition, the problems of adhesive overflow and adhesive shortage are prone to occur due to the limitation of process precision, which is not conducive to the a yield rate and operational reliability of the finally formed display device 200.

However, in the embodiments of the present application, since in the direction parallel to the plane on which the cover plate 20 is located, the limiting member 30 and the cover plate 20 extend beyond the display panel 10, the two may jointly define to form the groove-like structure C. The groove-like structure C can play a certain role in blocking the adhesive during an adhesive application process, such that the formed encapsulation adhesive 40 may be limited to a location of the groove-like structure C, and the encapsulation adhesive 40 may maintain a certain dimension and shape. In this manner, the reliability of a relative position of the encapsulation adhesive 40 can be improved, and the occurrence possibility of problems such as adhesive overflow and adhesive shortage can be reduced. Therefore, the yield rate of the display device 200 can be improved, and the reliability of sweat resistance, alkali resistance, and oil resistance of the display device 200 can be improved.

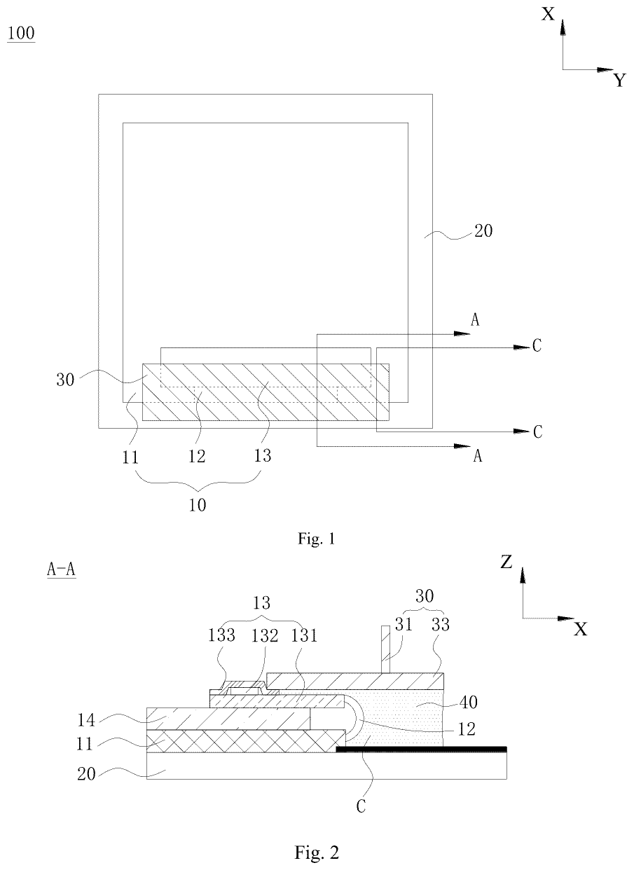

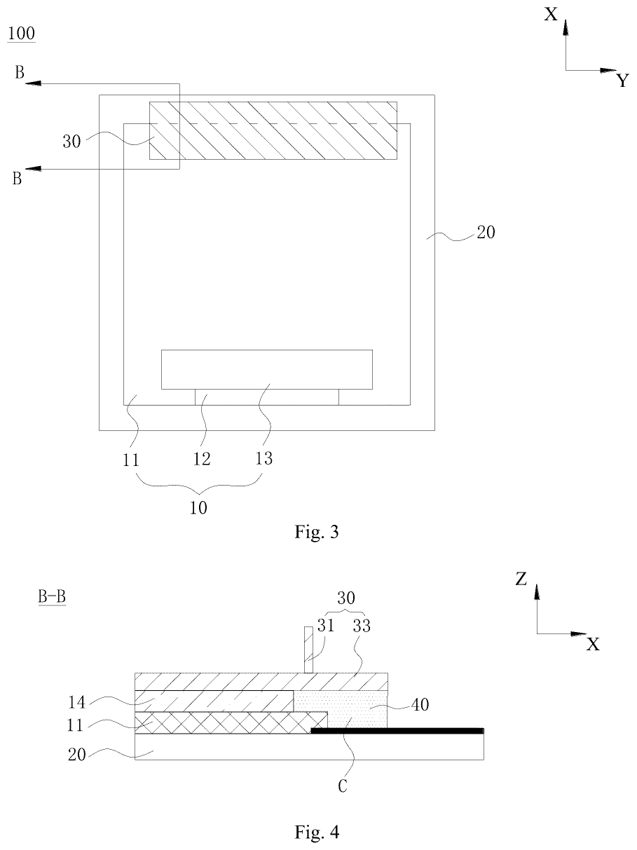

It should be noted that the expression “direction parallel to the plane on which the cover plate 20 is located” mentioned in the embodiments of the present application refers to a direction perpendicular to the thickness direction Z, which may refer to a specific direction or a plurality of different directions, and it is not limited in the embodiments of the present application. Specifically, taking for example that the finally formed display device 200 is a mobile phone, the cover plate 20 typically extends beyond the display panel 10 at four positions: an upper bezel, a lower bezel, a left bezel, and a right bezel of the display module 100. For the limiting member 30, the limiting member 30 may be provided only at one position of the upper bezel, the lower bezel, the left bezel, and the right bezel. For example, the limiting member 30 is provided at the left bezel, and in this case, the “direction parallel to the plane on which the cover plate 20 is located” refers to an arrangement direction of the left bezel and the right bezel, that is, refers to one single specific direction. Alternatively, the limiting member 30 may be provided at a plurality of positions of the upper bezel, the lower bezel, the left bezel, and the right bezel. For example, the limiting member 30 is provided at the left bezel and the lower bezel simultaneously, and in this case, the “direction parallel to the plane on which the cover plate 20 is located” refers to both an arrangement direction of the left bezel and the right bezel and an arrangement direction of the upper bezel and the lower bezel, that is, refers to a plurality of different directions. FIGS. 1 and 2 show a case where the limiting member 30 is provided only at the lower bezel, and FIGS. 3 and 4 show a case where the limiting member 30 is provided only at the upper bezel.

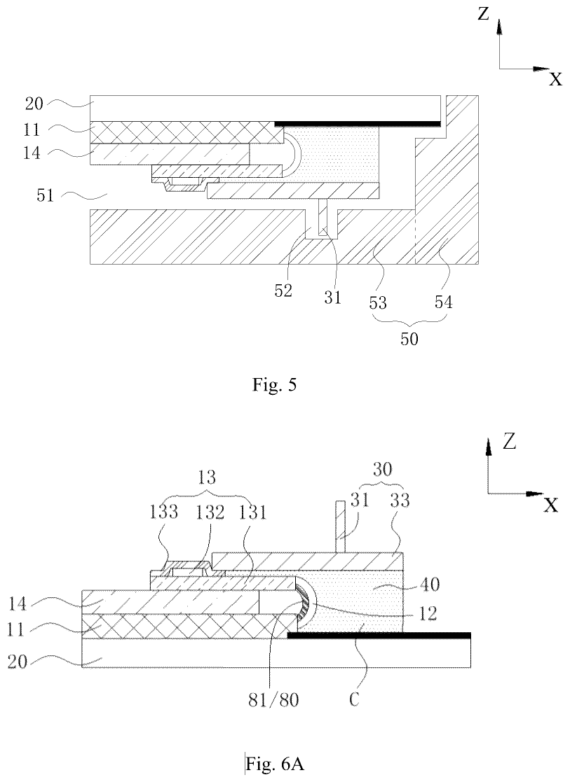

In addition, the limiting member 30 not only is configured to meet the formation requirements of the encapsulation adhesive 40, but also includes the limiting portion 31 that fits and is to assembled with the mid-frame 50. Exemplarily, the limiting portion 31 may include a protrusion structure, while the mid-frame 50 may include a recess structure, and the two may be assembled in a plug-in manner; or, the limiting portion 31 may include a protrusion structure, while the mid-frame 50 may include a recess structure, and the two may be assembled in a plug-in manner. FIG. 5 shows a case where the limiting portion 31 may include a recess structure while the mid-frame 50 may include a protrusion structure.

According to the above-described embodiments of the present application, by adding the limiting member 30 in the display module 100, and defining a dimension and a shape of the limiting member 30 and its position relative to the display panel 10, the display module 100 may have the groove-like structure C for accommodating the encapsulation adhesive 40, whereby a molding reliability of the encapsulation adhesive 40 can be improved, and the occurrence possibility of problems such as adhesive overflow and adhesive shortage can be reduced. Moreover, in the finally formed display device 200, the limiting member 30 may also be assembled with the mid-frame 50, such that a relative position between the display module 100 and the mid-frame 50 can be defined by the limiting member 30, a risk of excessive displacement of the display module 100 relative to the mid-frame 50 can be reduced, and an impact resistance and operational reliability of the display device 200 can be improved. In some embodiments, as shown in FIGS. 1 and 2, the display panel 10 includes a display portion 11, a bending portion 12, and a binding portion 13. The display portion 11 and the binding portion 13 are both connected to the bending portion 12, and the binding portion 13 is bent to a side of the display portion 11 away from the cover plate 20 via the bending portion 12. A projection of the limiting member 30 in the thickness direction Z overlaps a projection of the bending portion 12 in the thickness direction Z.

The display portion 11 is a main functional component of the display panel 10, and has a light-emitting surface and a backlight surface. The display portion 11 typically includes multiple different film layers arranged in a stacked manner. For example, the display portion 11 includes an array layer, a light-emitting layer, an optical adhesive layer and so on arranged in a stacked manner. The light-emitting structure may be provided in the light-emitting layer, and the cover plate 20 may be bonded and fixed to the display panel 10 by the optical adhesive layer.

The binding portion 13 is a component for integrating the structures such as a flexible circuit board and a driver chip 132 in the display panel 10. In order to reduce the adverse influence of the presence of the binding portion 13 on the bezel dimension, the binding portion 13 and the display portion 11 are not arranged side by side in a direction parallel to the plane on which the cover plate 20 is located, but are arranged spaced from each other in the thickness direction Z, and are connected to each other via the bending portion 12.

In the embodiments of the present application, the bending portion 12 is typically provided at the position of the lower bezel of the display module 100. On this basis, at least a partial structure of the limiting member 30 may exist at the position of the lower bezel of the display module 100 by providing the projection of the limiting member 30 in the thickness direction Z overlapping the projection of the bending portion 12 in the thickness direction Z. Under this condition, the groove-like structure C for accommodating the encapsulation adhesive 40 may exist at the location of the lower bezel, whereby the adverse influence of the bending shape of the bending portion 12 on the manufacturing process of the encapsulation adhesive 40 can be reduced, and the structural reliability of the encapsulation adhesive 40 at the position of the lower bezel can be improved.

It should be noted that, in the embodiments of the present application, depending on different actual needs, the limiting member 30 may be provided only at the position of the lower bezel, or may be provided not only at the position of the lower bezel but also at the positions of the other bezels, and it is not limited in the embodiments of the present application, as long as the limiting member 30 is at least partially located at the lower bezel position to provide the groove-like structure C at the position of the lower bezel.

In addition, the positional relationship between the limiting member 30 and the binding portion 13 is not limited in the embodiments of the present application. Exemplarily, a projection of the limiting member 30 in the thickness direction Z may be located outside a projection of the binding portion 13 in the thickness direction Z, or a projection of the limiting member 30 in the thickness direction Z may overlap a projection of the binding portion 13 in the thickness direction Z.

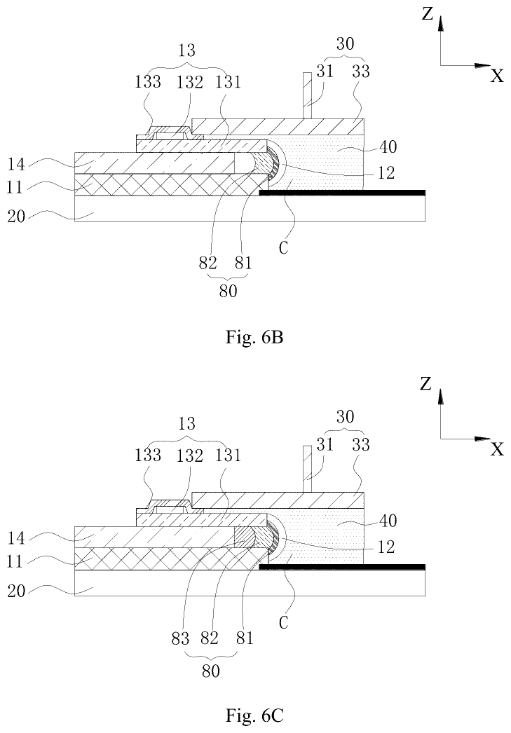

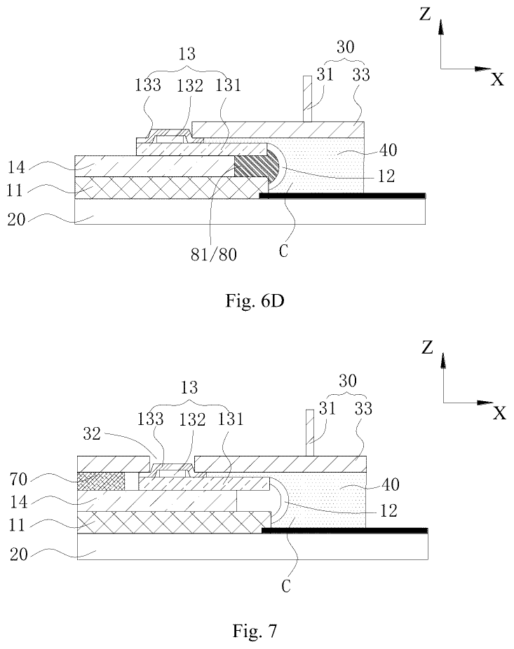

With respect to an adhesive structure on the peripheral sides of the display module, FIGS. 2 and 4 schematically illustrate a case where only the encapsulation adhesive 40 is provided, that is, a case where the adhesive structure is provided only on an outer side of the bending portion 12. However, depending on different actual needs, the adhesive structure may be optionally provided on an inner side of the bending portion 12. Referring to FIGS. 6A to 6D, if the adhesive structure 80 is provided on the inner side of the bending portion 12, the adhesive structure 80 may have various forms. Specifically, as shown in FIGS. 6A and 6D, the adhesive structure 80 may include only a first adhesive portion 81. In another case, as shown in FIG. 6B, the adhesive structure 80 may include a first adhesive portion 81 and a second adhesive portion 82, and the first adhesive portion 81 and the second adhesive portion 82 are formed respectively in different processes by dispensing. In a further another case, as shown in FIG. 6C, the adhesive structure 80 may include a first adhesive portion 81, a second adhesive portion 82, and a third adhesive portion 83, and the first adhesive portion 81, the second adhesive portion 82, and the third adhesive portion 83 are formed respectively in different processes by dispensing. Among them, FIGS. 6a and 6b both show a case where the adhesive structure 80 does not completely fill a gap space on the inner side of the bending portion 12, while in other cases, as shown in FIGS. 6C and 6D, the adhesive structure 80 may also completely fill the gap space on the inner side of the bending portion 12.

In some embodiments, as shown in FIGS. 1 and 2, a projection of the limiting member 30 in the thickness direction Z overlaps a projection of the binding portion 13 in the thickness direction Z, and the limiting member 30 is connected to the binding portion 13.

It can be seen from the drawings that, the bending portion 12 is located on the side of the display portion 11 in the first direction X, and the structure at the position of the lower bezel of the limiting member 30 extends beyond two sides of the bending portion 12 in the first direction X. The partial structure of the limiting member 30 extends beyond the side of the bending portion 12 away from the binding portion 13 is configured to define and form the groove-like structure C jointly with the cover plate 20, and the partial structure of the limiting member 30 exceeding the side of the bending portion 12 facing the binding portion 13 is configured to connect with the binding portion 13 to achieve the relative fixation between the display panel 10 and the limiting member 30.

In the embodiments of the present application, a projection dimension of the limiting member 30 in the thickness direction Z is limited such that it can overlap the binding portion 13. On this basis, considering that the shape of the binding portion 13 is typically flatter than that of the bending portion 12, the limiting member 30 is selected to be connected to the binding portion 13, thereby reducing the connection difficulty of the limiting member 30 to the display panel 10 and helping to improve the connection reliability between the limiting member 30 and the display panel 10.

In other embodiments, the limiting member 30 may extend beyond a side of the binding portion 13 away from the bending portion 12 in the first direction X, and in this case, the limiting member 30 may be connected to the display portion 11, satisfying the fixing needs between the limiting member 30 and the display panel 10.

In some embodiments, as shown in FIGS. 1 and 2, the binding portion 13 includes a body portion 131, a driver chip 132 provided on a side of the body portion 131 away from the display portion 11, and a protection portion 133 provided on a side of the driver chip 132 away from the display portion 11. The limiting member 30 is provided on a side of the protection portion 133 away from the display portion 11 and connected to the protection portion 133.

The binding portion 13 includes at least a body portion 131, a driver chip 132, and a protection portion 133. The driver chip 132 is provided on a side of the body portion 131 away from the display portion 11. A plurality of types of the driver chip 132 may be provided. For example, the binding portion 13 may include at least one of a display driver chip and a touch driver chip. The display driver chip 132 is configured to store image data, generate a driving voltage, and improve image quality by a customized algorithm. The touch driver chip mainly implements touch signal processing, and is an essential component of a display device 200 having a touch function. The display driver chip 132 and the touch driver chip 132 may be integrally provided on the body portion 131.

The protection portion 133 is provided on a side of the driver chip 132 away from the display portion 11 and can protect the driver chip 132. Further optionally, the protection portion 133 may adopt a structure such as an adhesive tape, allowing it to envelop the driver chip 132 while also being adhesively fixed to the body portion 131. This enhances the reliability of the relative position between the driver chip 132 and the body portion 131.

Furthermore, in the embodiments of the present application, the dimension of the limiting member 30 is adjusted such that it is provided on a side of the protection portion 133 away from the display portion 11 and connected to the protection portion 133, thereby achieving relative fixation between the limiting member 30 and the display panel 10. In addition, this design allows the body portion 131 and the limiting member 30 being spaced from each other in the thickness direction Z. Under this condition, during the adhesive application process, part of the adhesive may move to the surface of a side of the body portion 131 away from the display portion 11 and contact with the body portion 131, thereby achieving the contact arrangement between the binding portion 13 and the encapsulation adhesive 40. In this manner, the risk of oil entering into the binding portion 13 can be reduced by the encapsulation adhesive 40, and operational reliability of the binding portion 13 can be improved.

In some embodiments, referring to FIG. 7, the display panel 10 further includes a support layer 14 provided between the binding portion 13 and the display portion 11. In the direction parallel to the plane on which the cover plate 20 is located, the support layer 14 and the limiting member 30 both extend beyond one end of the binding portion 13 away from the bending portion 12, and the limiting member 30 is connected to the support layer 14.

The support layer 14 is a functional film layer provided between the binding portion 13 and the display portion 11 and has a supporting effect on the display portion 11. The two surfaces of the support layer 14 in the thickness direction Z may be provided in contact with the binding portion 13 and the display portion 11 respectively, and thus the support layer 14 also contributes to improving the reliability of the relative position between the binding portion 13 and the display portion 11. The support layer 14 may include a plurality of film layer structures arranged in a stacked manner, and the specific film layer composition form and material type of the support layer 14 are not limited in the embodiments of the present application.

In the embodiments of the present application, the support layer 14 and the limiting member 30 both extend beyond a side of the binding portion 13 away from the bending portion 12 in the first direction X. On this basis, partial structures of the support layer 14 and the limiting member 30 extending beyond the binding portion 13 may be connected to each other to meet the fixing needs between the limiting member 30 and the display panel 10. Since the surfaces of the support layer 14 in the thickness direction Z are typically flat, this design also contributes to reducing the connection difficulty between the limiting member 30 and the display panel 10 and improving the fixation reliability between them.

The specific connection method between the limiting member 30 and the support layer 14 is not limited in the embodiments of the present application. Optionally, the display module 100 further includes an adhesive layer 70 provided between the limiting member 30 and the support layer 14, and the limiting member 30 is connected and fixed to the support layer 14 by the adhesive layer 70.

It should be noted that, the above two embodiments are two connection methods between the limiting member 30 and the display panel 10, and on this basis, at least one of the two connection methods may be selected to achieve relative fixation between the limiting member 30 and the display panel 10 depending on different actual needs, which has a relatively high flexibility and applicability. Exemplarily, the structure at the position of the lower bezel of the limiting member 30 may be connected only to the protection portion 133, or may be connected only to the support layer 14, or may be connected to both the protection portion 133 and the support layer 14.

In some embodiments, as shown in FIG. 7, the limiting member 30 includes an avoidance hole 32 which penetrates through the limiting member 30 in the thickness direction Z, and a projection of the driver chip 132 in the thickness direction Z overlaps a projection of the avoidance hole 32 in the thickness direction Z.

It can be seen, from the above contents, that the projection of the limiting member 30 in the thickness direction Z may overlap the projection of the binding portion 13 in the thickness direction Z, and considering that the driver chip 132 is located in the binding portion 13, in order to reduce the influence of the limiting member 30 on the driver chip 132, in the embodiments of the present application, the limiting member 30 includes the avoidance hole 32 which corresponds to the driver chip 132 to achieve an avoidance effect. With this design, the risk of external stress being sequentially transmitted through the mid-frame 50 and the limiting member 30 to the driver chip 132 can be reduced, a stress impact on the driver chip 132 can be reduced, and the operational reliability of the finally formed display device 200 can be improved.

In some optional embodiments, a projection of the avoidance hole 32 in the thickness direction Z covers a projection of the driver chip 132 in the thickness direction Z, such that a projection of the limiting member 30 in the thickness direction Z may be completely outside a projection of the driver chip 132 in the thickness direction Z, thereby further reducing the stress impact on the driver chip 132.

In some embodiments, as shown in FIGS. 1 and 2, the bending portion 12 is located on the side of the display portion 11 in the first direction X, and a dimension of the limiting member 30 in the second direction Y is less than a dimension of the display portion 11 in the second direction Y. The first direction X and the second direction Y are both parallel to the plane on which the cover plate 20 is located, and the first direction X and the second direction Y intersect each other.

In connection with the display module 100, the first direction X may be an arrangement direction of the upper bezel and the lower bezel in the display module 100, and the second direction Y may be an arrangement direction of the left bezel and the right bezel in the display module 100. Optionally, any two of the first direction X, the second direction Y, and the thickness direction Z are perpendicular to each other.

In the embodiments of the present application, the limiting member 30 is provided only on the lower bezel of the display module 100, and the dimension of the limiting member 30 in the second direction Y is less than the dimension of the display portion 11 in the second direction Y. With this design, the groove-like structure C is only located on a local area of the lower bezel, thereby improving the structural reliability of the encapsulation adhesive 40 at the local position of the lower bezel, and simultaneously reducing the overall dimension of the limiting member 30, reducing an influence of the limiting member 30 on a weight of the finally formed display device 200, and facilitating the lightening and thinning design.

It should be noted that, the display portion 11 typically extends beyond the bending portion 12 in the second direction Y. On this basis, the dimensional relationship between the limiting member 30 and the bending portion 12 in the second direction Y is not limited in the embodiments of the present application. Exemplarily, the dimension of the limiting member 30 in the second direction Y may be greater than the dimension of the bending portion 12 in the second direction Y, or the dimension of the limiting member 30 in the second direction Y may be less than or equal to the dimension of the bending portion 12 in the second direction Y.

In some embodiments, referring to FIGS. 1, 2, and 8, the display module 100 further includes blocking members 60 which are filled in the groove-like structure C, and two of the blocking members 60 are provided spaced from each other in the second direction Y.

The blocking member 60 is a member for preventing the risk of overflow of the encapsulation adhesive 40 in the groove-like structure C in the second direction Y, and is provided in the groove-like structure C and fixed to the limiting member 30 and the display panel 10. Exemplarily, the blocking member 60 may be connected to at least one of the limiting member 30 and the display panel 10 by welding or the like, or the blocking member 60 may be relatively fixed to the limiting member 30 and the display panel 10 by pressing and filling.

There are at least two blocking members 60, two of which are provided spaced from each other in the second direction Y. There may be multiple positional relationships between the blocking member 60 and the groove-like structure C. Exemplarily, one single blocking member 60 may be provided at an end position of the groove-like structure C in the second direction Y, or may be provided at a middle position of the groove-like structure C in the second direction Y. Furthermore, there may be multiple positional relationships between the blocking member 60 and the display panel 10. Exemplarily, one single blocking member 60 may be provided corresponding to a partial structure of the bending portion 12 or the binding portion 13 in the second direction Y, or may be located on a side of the bending portion 12 and a side of the binding portion 13 in the second direction Y.

In addition, the specific material composition of the blocking member 60 is not limited in the embodiments of the present application. The blocking member 60 may include the same material at different positions, or the blocking member 60 may also include different structures having different materials, as long as the two blocking members 60 may fitted with each other to block the groove-like structure C in the second direction Y.

In a word, in the case where the groove-like structure C is only provided on the lower bezel of the display module 100, in the embodiments of the present application, the blocking members 60 are added in the groove-like structure C, and two of the blocking members 60 are provided spaced from each other in the second direction Y, thereby playing a blocking role for the encapsulation adhesive 40 in the second direction Y. In this manner, the limitation of the structure and relative position of the encapsulation adhesive 40 can be further improved, and the structural reliability of the encapsulation adhesive 40 can be further improved through the joint action of the limiting member 30, the blocking members 60, and the cover plate 20.

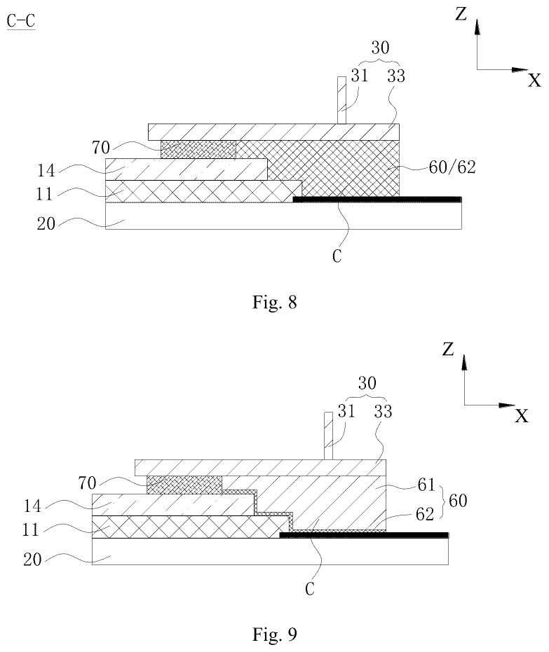

In some embodiments, as shown in FIGS. 1 and 8, the display portion 11 extend beyond the bending portion 12 in the second direction Y, and two of the blocking members 60 are provided on two sides of the bending portion 12 in the second direction Y respectively.

A dimension of the display portion 11 in the second direction Y is greater than a dimension of the bending portion 12 in the second direction Y, and projections of the two blocking members 60 in the thickness direction Z do not overlap with the bending portion 12, but are provided respectively on two sides of the bending portion 12 in the second direction Y. On the one hand, this design may reduce a pressing influence of the presence of the blocking members 60 on the bending portion 12 and improve a structural reliability of the bending portion 12; on the other hand, the shape and dimension of the blocking members 60 are no longer affected by the bending portion 12, which may facilitate increasing the dimension of the blocking members 60 in the thickness direction Z, improving the blocking effect of the blocking members 60 and further reducing the risk of overflow of the encapsulation adhesive 40 in the second direction Y.

In some embodiments, referring to FIGS. 8 and 9, the blocking member 60 includes a first portion 61 connected to the limiting member 30, and the first portion 61 includes a same material as the limiting member 30; and/or the blocking member 60 includes a buffer portion 62 in contact with the display portion 11, and a structural strength of the buffer portion 62 is less than a structural strength of the limiting member 30.

In order to achieve a better blocking effect, it is required that the two ends of the blocking member 60 in the thickness direction Z are in contact with the limiting member 30 and the display portion 11 respectively. Considering that in the finally formed display device 200, the limiting member 30 is assembled and fitted with the mid-frame 50, and an external impact force may be transmitted to the limiting member 30 through the mid-frame 50 and further transmitted to the blocking member 60 through the limiting member 30 during use or transportation processes, on this basis, in order to reduce a deformation degree of the partial structure of the blocking member 60 in contact with the limiting member 30, in the embodiments of the present application, the first portion 61 of the blocking member 60 in contact with the limiting member 30 is set to include the same material as the limiting member 30, such that the first portion 61 may have a same relatively strong structural strength as the limiting member 30, thereby reducing the risk of deformation of the first portion 61 due to impact and improving an operational reliability of the blocking member 60.

The specific forming method of the first portion 61 is not limited in the embodiments of the present application. Optionally, the first portion 61 and the limiting member 30 may have an integral structure. Furthermore, the first portion 61 and the limiting member 30 may both be sheet metal parts and may be manufactured by a sheet metal stamping process. Alternatively, in other embodiments, the first portion 61 and the limiting member 30 may have separate structures, and the two may be connected and fixed by welding, bonding, and so on.

With respect to the partial structure of the blocking member 60 in contact with the display portion 11, an external impact influence on the blocking member 60 is transmitted to the display portion 11 through this partial structure. On this basis, in order to reduce the stress influence of the blocking member 60 on the display portion 11, in the embodiments of the present application, the buffer portion 62 may be provided in the blocking member 60, and the buffer portion 62 has a smaller structural strength than the limiting member 30, thereby achieving a stress buffer effect, reducing the stress influence of the blocking member 60 on the display portion 11, and improving the operational reliability of the display panel 10.

The specific material composition of the buffer portion 62 is not limited in the embodiments of the present application. Optionally, the buffer portion 62 includes a foam material. On this basis, the buffer portion 62 may not only buffer stress to improve the reliability of the display portion 11, but also fill the groove-like structure C, thereby improving the blocking effect of the blocking member 60 on the groove-like structure C, and reducing the risk of overflow of the encapsulation adhesive 40 in the second direction Y.

It should be noted that, depending on different actual needs, the blocking member 60 may include only the first portion 61. Alternatively, as shown in FIG. 7, the blocking member 60 may include only the buffer portion 62. Alternatively, as shown in FIG. 8, the blocking member 60 may include both the first portion 61 and the buffer portion 62, which is not limited in the embodiments of the present application.

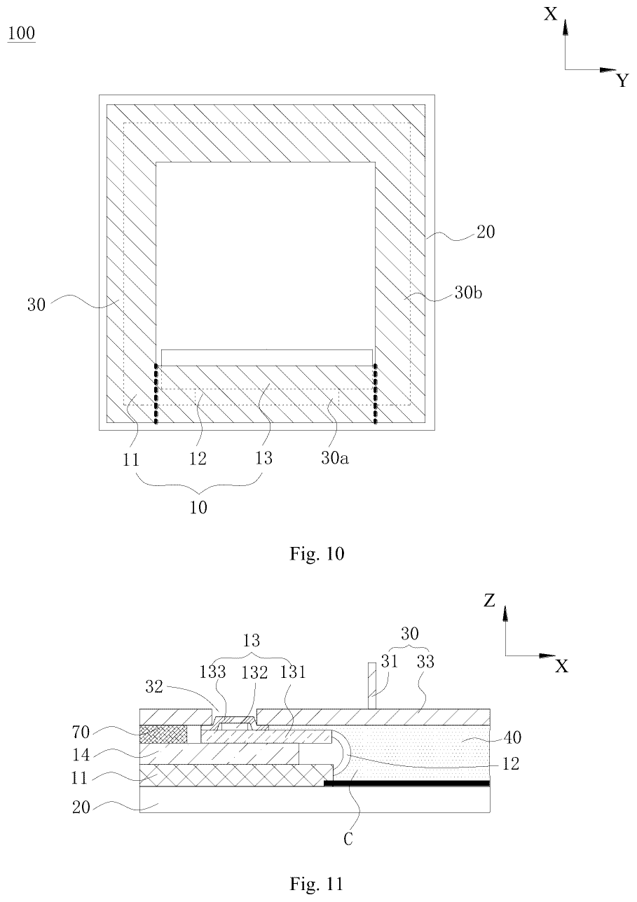

In some embodiments, referring to FIG. 10, a projection of the limiting member 30 in the thickness direction Z is provided around a peripheral side of a projection of the display panel 10 in the thickness direction Z.

It can be seen from the drawings that a projection of the limiting member 30 in the thickness direction Z may have a ring structure. On this basis, a projection of the groove-like structure C jointly formed by the limiting member 30, the cover plate 20, and the display panel 10 in the thickness direction Z may also have a ring structure and surrounds the peripheral side of the display panel 10. In other words, the display module 100 has the groove-like structures C at the positions of the upper bezel, the lower bezel, the left bezel, and the right bezel. Among them, the groove-like structure C located at the position of the lower bezel may refer to the structure shown in FIG. 6a-6d, and the groove-like structure C located at the positions of the upper bezel, the left bezel, and the right bezel may refer to the structure shown in FIG. 4.

The fixing method between the limiting member 30 and the display panel 10 is not limited in the embodiments of the present application. Optionally, the limiting member 30 may be connected to at least one of the binding portion 13 and the support layer 14 at the position of the lower bezel. Alternatively, the limiting member 30 may be connected to the support layer 14 or the display portion 11 at least one of the positions of the upper bezel, the left bezel, and the right bezel.

In the embodiments of the present application, the groove-like structure C may be provided around the peripheral side of the display panel 10 by adjusting the dimension and shape of the limiting member 30. In this manner, the display module 100 has the groove-like structure C at the positions of the upper bezel, the lower bezel, the left bezel, and the right bezel, thereby improving the formation reliability of the encapsulation adhesive 40 at different positions on the peripheral side of the display module 100 and improving the encapsulation effect of the encapsulation adhesive 40 at different positions on the peripheral side of the display panel 10.

In some embodiments, referring to FIGS. 4 and 10, the limiting member 30 includes a first limiting sub-portion 30a and a second limiting sub-portion 30b integrally connected in a circumferential direction of the display panel 10, a projection of the first limiting sub-portion 30a in the thickness direction Z overlaps a projection of the binding portion 13 in the thickness direction Z, and a projection of the second limiting sub-portion 30b in the thickness direction Z is located outside a projection of the binding portion 13 in the thickness direction Z. The display module 100 further includes a support layer 14 provided between the display portion 11 and the binding portion 13, and the second limiting sub-portion 30b is connected to the support layer 14. In FIG. 10, a boundary line between the first limiting sub-portion 30a and the second limiting sub-portion 30b is schematically indicated by a bold black dashed line.

The first limiting sub-portion 30a is a structure located at the position of the lower bezel of the limiting member 30, and the second limiting sub-portion 30b is a structure located at positions of the upper bezel, the left bezel, and the right bezel of the limiting member 30. Specifically, the second limiting sub-portion 30b includes a first sub-portion, a second sub-portion, and a third sub-portion. The first sub-portion is a structure located at the position of the upper bezel, and the first sub-portion and the first limiting sub-portion 30a are provided side by side in the first direction X. The second sub-portion is a structure located at the position of the left bezel, the third sub-portion is a structure located at the position of the right bezel, and the second sub-portion and the third sub-portion are provided side by side in the second direction Y. Two ends of the second sub-portion in the first direction X are connected to the first limiting sub-portion 30a and the first sub-portion as an integrated structure, and two ends of the third sub-portion in the first direction X are connected to the first limiting sub-portion 30a and the first sub-portion as an integrated structure.

In the embodiments of the present application, in the case where the limiting member 30 has a ring structure, the second limiting sub-portion 30b is connected to the support layer 14 to satisfy the fixing requirement between the limiting member 30 and the display panel 10. Since the surfaces of the support layer 14 in the thickness direction Z are typically flat, this design also contributes to reducing the connection difficulty between the limiting member 30 and the display panel 10 and improving the fixation reliability between the two.

It should be noted that, the first limiting sub-portion 30a may be connected to the display panel 10, or the first limiting sub-portion 30a may not be connected to the display panel 10, and it is not limited in the embodiments of the present application. In the case where the first limiting sub-portion 30a is connected to the display panel 10, the first limiting sub-portion 30a may optionally be connected to the protection portion 133, or the first limiting sub-portion 30a may extend beyond a side of the binding portion 13 away from the bending portion 12 in the first direction X and connected to the support layer 14.

In some embodiments, as shown in FIG. 7, the limiting member 30 includes a connecting portion 33 connected to the display panel 10, and the limiting portion 31 protruding on a side of the connection portion 33 away from the display panel 10. In the direction parallel to the plane on which the cover plate 20 is located, the connection portion 33 extend beyond the display panel 10.

The limiting member 30 includes at least two structures, i.e., the connection portion 33 and the limiting portion 31, in which the limiting portion 31 is a functional member of the limiting member 30 for fitting and assembling with the mid-frame 50, and the connection portion 33 is a functional member of the limiting member 30 for connecting with the display panel 10. Depending on different actual needs, the limiting portion 31 and the connection portion 33 may be made of a same material and have an integral structure, or they may be made of different materials and connected and fixed by welding or the like, and it is not limited in the embodiments of the present application.

In the embodiments of the present application, the limiting portion 31 is located on the side of the connection portion 33 away from the display panel 10, and is configured to protrude relative to the connection portion 33 in the thickness direction Z. In this manner, on the one hand, a side of the connection portion 33 away from the limiting portion 31 may be connected to the display panel 10, thereby reducing an influence of the limiting portion 31 on the connection between the connection portion 33 and the display panel 10; on the other hand, a side of the connection portion 33 away from the display panel 10 may be in a plug-in fit with a bottom plate 53 of the mid-frame 50, thereby reducing the influence of the display panel 10 on the assembly of the limiting member 30 and the mid-frame 50.

In addition, the connection portion 33 extends beyond the display panel 10 in the direction parallel to the plane on which the cover plate 20 is located. It can be seen that the connection portion 33 is not only configured to connect with the display panel 10, but also configured to fit with the display panel 10 and the cover plate 20 to form the groove-like structure C, thereby improving the structural reliability of the encapsulation adhesive 40.

The specific shape and dimensional relationship between the connection portion 33 and the limiting portion 31 is not limited in the embodiments of the present application. Exemplarily, projections of the connection portion 33 and the limiting portion 31 in the thickness direction Z both have a stripe structure, and are provided at the position of the lower bezel of the display module 100. Alternatively, a projection of the connection portion 33 in the thickness direction Z may have a ring structure, and in this case, a projection of the limiting portion 31 in the thickness direction Z may be a stripe structure provided at the specific position of the bezel, may include a plurality of stripe structures spaced from each other, or may also have a ring structure.

Furthermore, in some optional embodiments, a projection of the limiting portion 31 in the thickness direction Z is located inside a projection of the connection portion 33 in the thickness direction Z. A projection of the limiting portion 31 in the thickness direction Z may overlap a projection of the display panel 10 in the thickness direction Z, or a projection of the limiting portion 31 in the thickness direction Z may located outside a projection of the display panel 10 in the thickness direction Z.

In some embodiments, as shown in FIG. 7, a projection of the limiting portion 31 in the thickness direction Z is located outside a projection of the display panel 10 in the thickness direction Z.

In a case where the projection of the limiting portion 31 in the thickness direction Z has a stripe structure and is provided at the position of the lower bezel, the limiting portion 31 may be located on a side of the bending portion 12 away from the display portion 11 in the first direction X. In a case where the projection of the limiting portion 31 in the thickness direction Z has a ring structure, the projection of the limiting portion 31 in the thickness direction Z is disposed around a projection of the display panel 10 in the thickness direction Z.

In the embodiments of the present application, a fitting position between the limiting member 30 and the mid-frame 50 may be misaligned with the display panel 10 in the direction parallel to the plane on which the cover plate 20 is located by providing a projection of the limiting portion 31 in the thickness direction Z outside a projection of the display panel 10 in the thickness direction Z, such that a stress transmission path may be increased. Under this condition, an external stress transmitted from the mid-frame 50 to the limiting member 30 cannot be directly transmitted to the display panel 10 in the thickness direction Z during use or transportation processes of the finally formed display device 200, whereby a stress influence on the display panel 10 can be reduced, and the operational reliability of the display device 200 can be improved.

In some embodiments, referring to FIGS. 5, 11, and 12, a projection of the limiting member 30 in the thickness direction Z coincides with an edge of a projection of the cover plate 20 in the thickness direction Z, or a projection of the cover plate 20 in the thickness direction Z covers and extends beyond a projection of the limiting member 30 in the thickness direction Z.

The limiting member 30 and the cover plate 20 may have multiple different dimensional relationships. On this basis, the mid-frame 50 may also have different dimensions and shapes. Specifically, the mid-frame 50 includes a bottom plate 53 and a side plate 54 connected to a peripheral side of the bottom plate 53, and the side plate 54 is provided on an outer peripheral side of the display module 100. In a case where the projection of the cover plate 20 in the thickness direction Z covers and extends beyond the projection of the limiting member 30 in the thickness direction Z, it can be seen from FIG. 5 that, the partial structure of the side plate 54 may be located below the cover plate 20, and projections of the two in the thickness direction Z overlap each other, thereby reducing the dimensions of the side plate 54 extending beyond the display module 100 in the direction parallel to the plane on which the cover plate 20 is located, and further reducing the bezel dimensions of the display device 200.

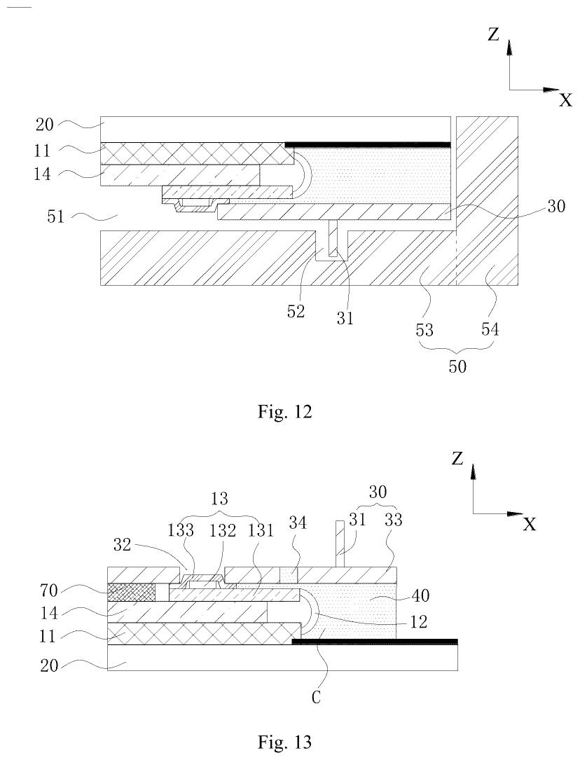

In another case, as shown in FIG. 12, when the projection of the limiting member 30 in the thickness direction Z coincides with the edge of the projection of the cover plate 20 in the thickness direction Z, the side plate 54 may be completely located on the side of the cover plate 20 in the direction parallel to the plane on which the cover plate 20 is located, and the projections of the two in the thickness direction Z do not overlap each other.

In a word, in the embodiments of the present application, the limiting member 30 and the cover plate 20 may have multiple different dimensional relationships to meet the operational requirements of different display devices 200, which has a relatively high flexibility and applicability. Further considering the siphon phenomenon, in the embodiments of the present application, the projection of the limiting member 30 in the thickness direction Z does not extend beyond the projection of the cover plate 20 in the thickness direction Z, thereby reducing the risk of overflow of the encapsulation adhesive 40 and improving the structural reliability of the encapsulation adhesive 40.

In some embodiments, referring to FIGS. 13 to 15, the limiting member 30 is provided with a via-hole structure 34 penetrating in the thickness direction Z, and the via-hole structure 34 communicates with the groove-like structure C.

The via-hole structure 34 is provided to penetrate the limiting member 30 in the thickness direction Z, and there may be one via-hole structure 34, or may be a plurality of via-hole structures 34. Optionally, there are a plurality of via-hole structures 34, and projections of the via-hole structures 34 in the thickness direction Z surround a peripheral side of the projection of the display panel 10 in the thickness direction Z with intervals.

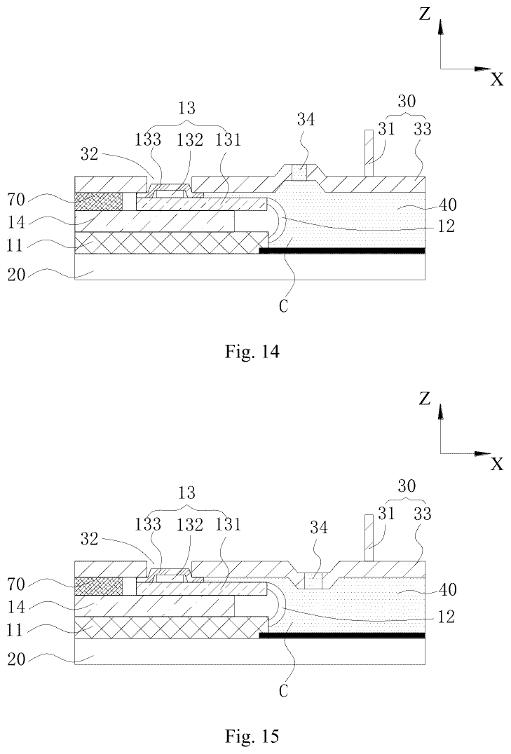

The via-hole structure 34 may have multiple shapes. For example, the via-hole structure 34 may have a circular-hole structure, a square-hole structure, a slit structure, and so on, and the specific shape and dimension of the via-hole structure 34 are not limited in the embodiments of the present application. Furthermore, there are multiple methods for forming the via-hole structure 34. Exemplarily, taking the example where the connection portion 33 in the limiting member 30 includes a sheet metal part, the via-hole structure 34 may be directly formed by punching the connection portion 33, or the boss structure may be can be stamped on the connection portion 33 first, and then a via can be punched on the boss structure to form the via-hole structure 34. As shown in FIG. 15, the boss structure may be formed by protruding the connection portion 33 in a direction approaching the cover plate 20, or as shown in FIG. 14, the boss structure may be formed by protruding the connection portion 33 in a direction away from the cover plate 20.

In the embodiments of the present application, by providing the via-hole structure 34 in the limiting member 30, the groove-like structure C may communicate with the external environment through the via-hole structure 34, and further, during the formation process of the encapsulation adhesive 40, the air in the groove-like structure C may be quickly discharged through the via-hole structure 34, thereby reducing the occurrence possibility of problems such as adhesive overflow. In addition, the encapsulation adhesive 40 may also enter into the via-hole structure 34 to improve a bonding strength between the encapsulation adhesive 40 and the limiting member 30.

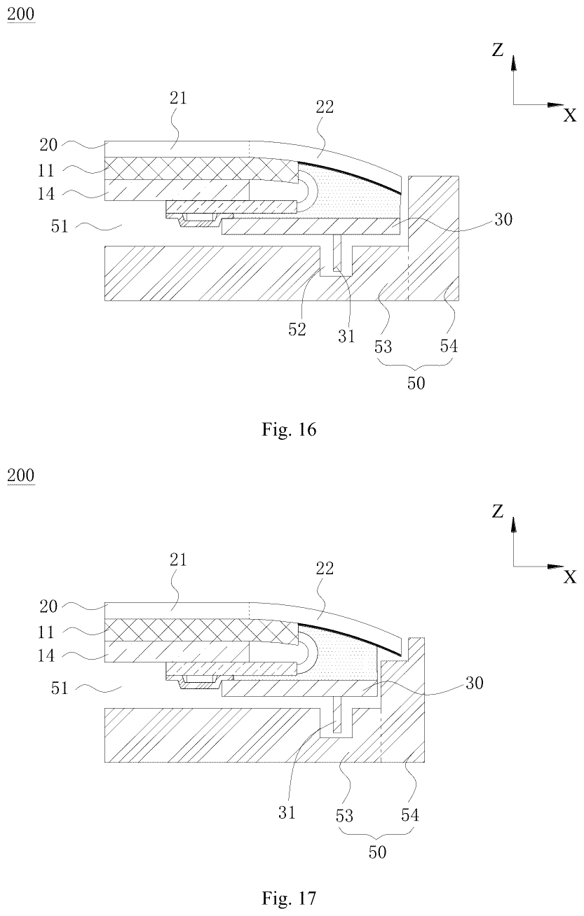

In some embodiments, referring to FIGS. 16 and 17, the cover plate 20 includes a cover plate body 21 and a curved portion 22 integrally connected to a peripheral side of the cover plate body 21, and the curved portion 22 is curved toward the display panel 10 in a direction away from a center of the cover plate 20.

The cover plate body 21 is a partial structure located at the center of the cover plate 20, and the curved portion 22 is a partial structure located at an edge of the cover plate 20. The cross-sectional of the curved portion 22 is in the curved shape; that is, the display module 100 is not flat at the position of the bezel but has a certain curvature.

In the embodiments of the present application, for the display device 200 with curved edges, the display device 200 has higher requirements for encapsulation effect due to the influences of its own structure, shape, and other factors. On this basis, the groove-like structure C for accommodating the encapsulation adhesive 40 is defined and formed by adding the limiting member 30 to such a display device 200 and by the fit between the limiting member 30, the display panel 10, and the cover plate 20, whereby the structural reliability of the encapsulation adhesive 40 can be improved, and thus the encapsulation effect of the display device 200 can be improved.

In a second aspect, the embodiments of the present application provide a display device 200 which includes a mid-frame and a display module 100 according to any one of the above embodiments. The surface of the mid-frame 50 in the thickness direction Z is recessed inwardly to form an accommodation groove 51, and a bottom surface of the accommodation groove 51 is recessed inwardly to form a limiting groove 52. The display panel 10 is located in the accommodation groove 51, and the limiting member 30 is partially located in the limiting groove 52.

The mid-frame 50 plays a role in protecting the display module 100. Specifically, the mid-frame 50 includes a bottom plate 53 and a side plate 54 connected to a peripheral side of the bottom plate 53, the side plate 54 being provided on an outer peripheral side of the display module 100, and the bottom plate 53 being provided on a side of the display module 100 in the thickness direction Z. The bottom plate 53 and the side plate 54 jointly enclose to form the accommodation groove 51. The surface of the bottom plate 53 facing the accommodation groove 51 is the bottom surface of the accommodation groove 51, and the limiting groove 52 is formed by the bottom surface of the bottom plate 53 being recessed inward.

It should be noted that, the display device 200 according to the embodiments of the present application has the beneficial effects of the display module 100 in any one of the above embodiments. For details, please refer to the above description of the beneficial effects of the display module 100, which will not be repeated in the embodiments of the present application.

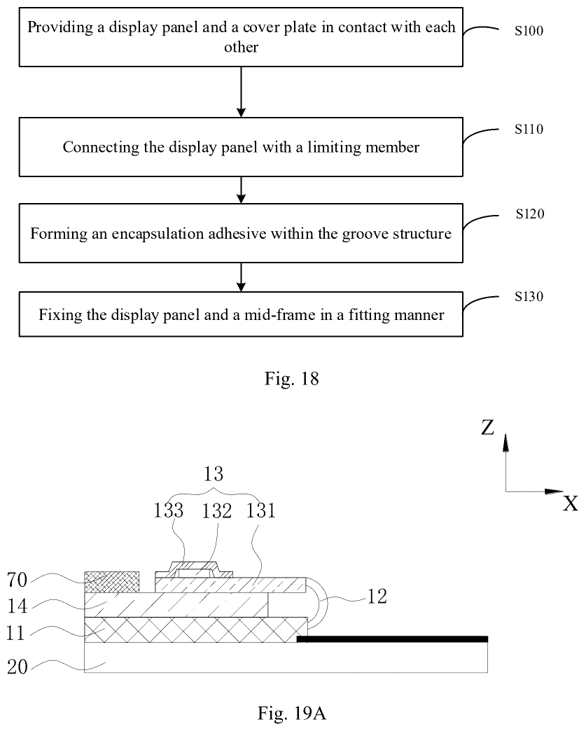

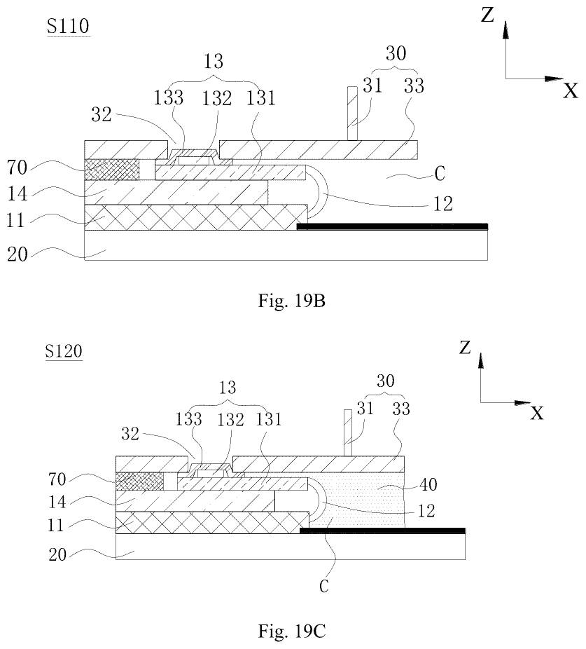

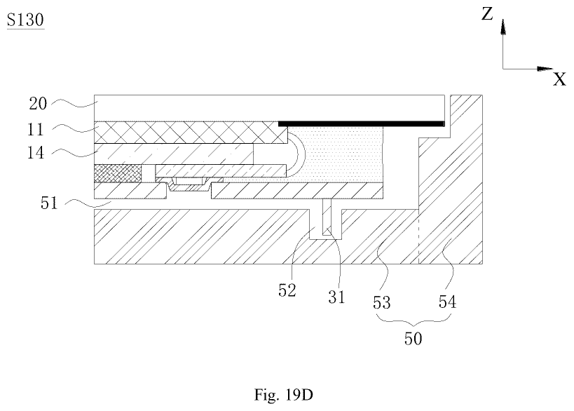

In a third aspect, referring to FIGS. 18 and 19A to 19D, the embodiments of the present application provide a manufacturing method for a display device 200, and the method includes the following steps S100-S130.

In S100, a display panel is attached to a cover plate.

Referring to FIG. 19A, in S100, the cover plate 20 is provided on a side of the display panel 10 in a thickness direction thereof. For example, the display panel 10 includes a display portion 11, a bending portion 12, and a binding portion 13. The display portion 11 and the binding portion 13 are both connected to the bending portion 12, and the binding portion 13 is bent to a side of the display portion 11 away from the cover plate 20 via the bending portion 12.

In S110, the display panel is connected with a limiting member.

Referring to FIG. 19B, in S110, the limiting member 30 is located on a side of the display panel 10 away from the cover plate 20, and the limiting member 30 and the cover plate 20 extend beyond the display panel 10 to form a groove-like structure C. The shape of the limiting member 30 may have multiple forms. For example, a projection of the limiting member 30 in the thickness direction Z may have a ring structure, and may be provided on the peripheral side of the display panel 10. Alternatively, the projection of the limiting member 30 in the thickness direction Z may have a stripe structure and may be provided at the position of the lower bezel.

In S120, an encapsulation adhesive is formed within the groove-like structure.

Referring to FIG. 19C, in S120, the encapsulation adhesive 40 may be formed in the groove-like structure C by coordinating rapid adhesive filling and dispensing. Specifically, the adhesive may be rapidly filled in the groove-like structure C first, and at this time, the adhesive droplets dropped into the groove-like structure C have a relatively large dimension and a relatively large quantity. The adhesive is then injected into the groove-like structure C by dispensing when the adhesive is nearly flush with an edge of at least one of the cover plate 20 and the blocking member 60, and at this time, the adhesive droplets dropped into the groove-like structure C have a relatively small dimension and a relatively small quantity.

In S130, the display panel and a mid-frame are fixed in a fitting manner.

Referring to FIG. 19D, in S130, a surface of the mid-frame 50 in the thickness direction Z is recessed inward to form an accommodation groove 51, and a bottom surface of the accommodation groove 51 is recessed inward to form a limiting groove 52. The display panel 10 is located in the accommodation groove 51, and the limiting member 30 is partially located in the limiting groove 52. Specifically, the limiting portion 31 is located in the limiting groove 52.

In the embodiments of the present application, the display device 200 may have the groove-like structure C for accommodating the encapsulation adhesive 40 by adding the limiting member 30, and defining a dimension and a shape of the limiting member 30 and its position relative to the display panel 10, whereby a molding reliability of the encapsulation adhesive 40 can be improved, and the occurrence possibility of problems such as adhesive overflow and adhesive shortage can be reduced. Moreover, the limiting member 30 may also be assembled and fitted with the mid-frame 50, such that a relative position between the display module 100 and the mid-frame 50 can be defined by the limiting member 30, a risk of excessive displacement of the display module 100 relative to the mid-frame 50 can be reduced, and an impact resistance and operational reliability of the display device 200 can be improved.

Although the embodiments are described above, the contents described herein are merely embodiments adopted to facilitate understanding of the present application, but are not intended to limit the present invention. Any person skilled in the art to which the present application belongs may make any modifications and changes in the form and details of implementation without departing from the gist and scope disclosed in the present application, but the scope of protection of the present application should still be defined by the scope of the appended claims.

The above are only specific implementations of the present application, those skilled in the art can clearly understand that, for the convenience and brevity of the description, the alternative connection methods can be referred to the corresponding processes in the foregoing method embodiments, which is not repeated here. It should be understood that, the protection scope of the present application is not limited to this, and any person skilled in the art can easily think of various equivalent modifications or replacements within the technical scope disclosed in the present application, and these modifications or replacements should all be covered within the scope of protection of the present application.

What is claimed is:

1. A display module, comprising:
a display panel;
a cover plate provided on a side of the display panel in a thickness direction thereof;
a limiting member connected to a side of the display panel away from the cover plate, a limiting portion being provided on a side of the limiting member away from the display panel, and the limiting portion being configured to fit with a mid-frame; and
an encapsulation adhesive provided on an outer peripheral side of the display panel,
wherein the limiting member and the cover plate extend beyond the display panel in a direction parallel to a plane on which the cover plate is located to form a groove-like structure for accommodating the encapsulation adhesive.

2. The display module according to claim 1, wherein the display panel comprises a display portion, a bending portion, and a binding portion, the display portion and the binding portion being connected to the bending portion, and the binding portion being bent to a side of the display portion away from the cover plate via the bending portion; and
wherein a projection of the limiting member in the thickness direction overlaps a projection of the bending portion in the thickness direction.

3. The display module according to claim 2, wherein the projection of the limiting member in the thickness direction overlaps a projection of the binding portion in the thickness direction, and the limiting member is connected to the binding portion.

4. The display module according to claim 2, wherein the binding portion comprises a body portion, a driver chip provided on a side of the body portion away from the display portion, and a protection portion provided on a side of the driver chip away from the display portion, and the limiting member is provided on a side of the protection portion away from the display portion and is connected to the protection portion; or
wherein the display panel further comprises a support layer provided between the binding portion and the display portion, the support layer and the limiting member extend beyond an end of the binding portion away from the bending portion in the direction parallel to the plane on which the cover plate is located, and the limiting member is connected to the support layer.

5. The display module according to claim 4, wherein the limiting member comprises an avoidance hole which runs through the limiting member in the thickness direction, and a projection of the driver chip in the thickness direction overlaps a projection of the avoidance hole in the thickness direction.

6. The display module according to claim 2, wherein the bending portion is located on a side of the display portion in a first direction, and a dimension of the limiting member in a second direction is less than a dimension of the display portion in the second direction, the first direction and the second direction being parallel to the plane on which the cover plate is located and intersecting each other.

7. The display module according to claim 6, further comprising blocking members filled in the groove-like structure, and two of the blocking members are provided spaced from each other in the second direction.

8. The display module according to claim 7, wherein the display portion extend beyond the bending portion in the second direction, and the two of the blocking members are provided on two sides of the bending portion in the second direction respectively.

9. The display module according to claim 7, wherein the blocking member comprises a first portion connected to the limiting member, and the first portion comprises a same material as that of the limiting member; or
wherein the blocking member comprises a buffer portion in contact with the display portion, and a structural strength of the buffer portion is less than a structural strength of the limiting member.

10. The display module according to claim 2, wherein a projection of the limiting member in the thickness direction is provided around a peripheral side of a projection of the display panel in the thickness direction.

11. The display module according to claim 10, wherein the limiting member comprises a first limiting sub-portion and a second limiting sub-portion integrally connected in a circumferential direction of the display panel, a projection of the first limiting sub-portion in the thickness direction overlaps a projection of the binding portion in the thickness direction, and a projection of the second limiting sub-portion in the thickness direction is located outside the projection of the binding portion in the thickness direction; and
wherein the display panel further comprises a support layer provided between the binding portion and the display portion, and the second limiting sub-portion is connected to the support layer.

12. The display module according to claim 1, wherein the limiting member comprises a connection portion connected to the display panel, the limiting portion protrudes from a side of the connection portion away from the display panel, and the connection portion extends beyond the display panel in the direction parallel to the plane on which the cover plate is located.

13. The display module according to claim 12, wherein a projection of the limiting portion in the thickness direction is located outside a projection of the display panel in the thickness direction.

14. The display module according to claim 1, wherein a projection of the limiting member in the thickness direction coincides with an edge of a projection of the cover plate in the thickness direction; or
wherein a projection of the cover plate in the thickness direction covers and extend beyond a projection of the limiting member in the thickness direction.

15. The display module according to claim 1, wherein the limiting member is provided with a via-hole structure penetrating therethrough in the thickness direction, and the via-hole structure communicates with the groove-like structure.

16. The display module according to claim 1, wherein the cover plate comprises a cover plate body and a curved portion integrally connected to a peripheral side of the cover plate body, and the curved portion is curved toward a direction close to the display panel in a direction away from a center of the cover plate.

17. A display device comprising a mid-frame and a display module, wherein a surface of the mid-frame in the thickness direction is recessed inward to form an accommodation groove, a bottom surface of the accommodation groove is recessed inward to form a limiting groove, a display panel is located in the accommodation groove, and the limiting member is partially located in the limiting groove;
wherein the display module comprises:
the display panel;
a cover plate provided on a side of the display panel in a thickness direction thereof;
a limiting member connected to a side of the display panel away from the cover plate, a limiting portion being provided on a side of the limiting member away from the display panel, and the limiting portion being configured to fit with a mid-frame; and
an encapsulation adhesive provided on an outer peripheral side of the display panel,
wherein the limiting member and the cover plate extend beyond the display panel in a direction parallel to a plane on which the cover plate is located to form a groove-like structure for accommodating the encapsulation adhesive.

18. A manufacturing method for a display device, comprising:
attaching a display panel to a cover plate, the cover plate being provided on a side of the display panel in a thickness direction thereof;
connecting the display panel with a limiting member, wherein the limiting member is located on a side of the display panel away from the cover plate, and the limiting member and the cover plate extend beyond the display panel to form a groove-like structure;
forming an encapsulation adhesive in the groove-like structure; and
fixing the display panel and a mid-frame in a fitting manner, wherein a surface of the mid-frame in the thickness direction is recessed inward to form an accommodation groove, a bottom surface of the accommodation groove is recessed inward to form a limiting groove, the display panel is located in the accommodation groove, and the limiting member is partially located in the limiting groove.

19. The display device according to claim 17, wherein the display panel comprises a display portion, a bending portion, and a binding portion, the display portion and the binding portion being connected to the bending portion, and the binding portion being bent to a side of the display portion away from the cover plate via the bending portion; and
wherein a projection of the limiting member in the thickness direction overlaps a projection of the bending portion in the thickness direction.

20. The display device according to claim 19, wherein the projection of the limiting member in the thickness direction overlaps a projection of the binding portion in the thickness direction, and the limiting member is connected to the binding portion.
